(19) United States
(12) Patent Application Publication
(10) Pub. No.: US 2014/0321034 A1
(43) Pub. Date: Oct. 30, 2014

(54) BATTERY PACK AND ELECTRICAL APPARATUS

(71) Applicant: HITACHI KOKI CO., LTD., Tokyo (JP)

(72) Inventor: Shota TAKEUCHI, Hitachinaka (JP)

(73) Assignee: HITACHI KOKI CO., LTD., Tokyo (JP)

(21) Appl. No.: 14/264,381

(22) Filed: Apr. 29, 2014

(30) Foreign Application Priority Data
Apr. 30, 2013 (JP) 2013-095192

(51) Int. Cl. H01M 2/10; H05K 5/02

(52) U.S. Cl. CPC H01M 2/1022; H05K 5/0217; H01M 2220/30
USPC 361/679.01; 429/163

(57) ABSTRACT

A battery pack allowing a gap between an electrical device and the battery pack to be narrowed is provided. The battery pack has a housing case that is slidably attached/detached to/from the electrical device, and an elastic member that exerts a force acting in a direction of causing a mounting unit provided to the electrical device and the housing case to move closer to each other.

### CROSS-REFERENCE TO RELATED APPLICATION

The present application claims priority from Japanese Patent Application No. 2013-095192 filed on Apr. 30, 2013, the content of which is hereby incorporated by reference into this application.

### TECHNICAL FIELD OF THE INVENTION

The present invention relates to a battery pack housing battery cells and to an electrical apparatus having a battery pack and an electrical device.

### BACKGROUND OF THE INVENTION

A conventional electrical apparatus is known, which includes a battery pack and an electrical device to/from which the battery pack is attached/detached, and an example of such an electrical apparatus is described in Japanese Patent Application Laid-Open Publication No. 2001-351592 (Patent Document 1). The electrical apparatus described in Patent Document 1 includes an electrical device made of a synthetic resin, a mounting unit provided to the lower end of the electrical device, and a battery pack attached/detached to/from the mounting unit. The mounting unit has device-side terminals, a pair of guide rails, a concave portion, and a coil spring disposed between the pair of guide rails. The coil spring is an elastic member that expands and contracts in the longitudinal direction of the pair of guide rails. The battery pack has battery-side terminals, a pair of slide rails, and a hook. The hook has a claw and an operation part.

To attach the battery pack to the mounting unit, the pair of guide rails and the pair of slide rails are engaged with each other and the battery pack is moved along the pair of guide rails to bring the battery pack closer to the mounting unit. As a result, the claw comes into contact with the mounting unit and slips therein as the battery pack comes into contact with the coil spring to compress it. When the battery pack is stopped at a given position, the claw is engaged with the concave portion. In this manner, when the battery pack is mounted to the mounting unit, the device-side terminals and the battery-side terminals are connected to each other.

To detach the battery pack from the mounting unit, the operation part is operated to disengage the claw from the concave portion. Upon disengaging the claw, the coil spring exerts its force to push the battery pack, thus moving the battery pack along the pair of guide rails. This move of the battery pack disengages the device-side terminals from the battery-side terminals. Hence the battery pack can be detached from the mounting unit. According to the electrical apparatus described in Patent Document 1, because the battery pack is pushed with the force of the coil spring, detaching the battery pack from the mounting unit is an easy work.

### SUMMARY OF THE INVENTION

However, according to the electrical apparatus described in Patent Document 1, pushing the battery pack with the force of the coil spring in a direction in which the battery pack is detached from the mounting unit readily leads to the expansion of a gap between the electrical device and the battery pack. This raise a possibility that a foreign object ingresses into a gap between the electrical device and the battery pack.

An object of the present invention is to provide a battery pack and an electrical apparatus capable of narrowing a gap between a battery pack and an electrical device.

A battery pack according to one embodiment includes a housing case slidably attached/detached to/from an electrical device; and an energizing member that exerts a force acting in a direction of causing a mounting unit provided to the electrical device and the housing case to move closer to each other.

A battery pack according to another embodiment includes a housing case slidably attached/detached to/from an electrical device; and an energizing member that, while the housing case is being mounted to a mounting unit provided to the electrical device, exerts a force acting in a direction of causing the mounting unit and the housing case to move closer to each other.

A battery pack according to still another embodiment includes a housing case housing battery cells and attached/detached to/from an electrical device; a latch mechanism disposed on the housing case and having a claw that is engage with a mounting unit provided to the electrical device and an operation part that operates the claw; and an energizing member that when the housing case is mounted to the mounting unit, exerts a force acting in a direction of causing the mounting unit and the housing case to move closer to each other.

A battery pack according to still another embodiment includes a housing case housing battery cells and attached/detached to/from an electrical device; a latch mechanism disposed in the housing case and having a claw that is engaged with a mounting unit provided to the electrical device and an operation part that operates the claw; and an energizing member that, while the housing case is being mounted to the mounting unit, applies energy to the latch mechanism in a direction of causing the latch mechanism to move away from the mounting unit.

An electrical apparatus according to still another embodiment includes a battery pack attached/detached to/from an electrical device, the battery pack having a housing case slidably attached/detached to/from the electrical device and an energizing member that exerts a force acting in a direction of causing a mounting unit provided to the electrical device and the housing case to move closer to each other.

A battery pack according to still another embodiment houses battery cells, and includes a housing case housing the battery cells and attached/detached to/from an electrical device; and an energizing member disposed in the housing case, the energizing member pushing the housing case to the electrical device in a direction in which the housing case is attached to the electrical device.

An electrical apparatus according to still another embodiment includes a battery pack attached/detached to/from an electrical device, the battery pack having a housing case housing the battery cells and attached/detached to/from the electrical device and an energizing member disposed in the housing case, the energizing member pushing the housing case to the electrical device in a direction in which the housing case is attached to the electrical device.

According to a battery pack of an embodiment, a gap between an electrical device and the battery pack can be narrowed. This can suppresses the rattling of the electrical device and the battery pack and can inhibit the ingress of a foreign object into a gap between the electrical device and the battery pack.

### BRIEF DESCRIPTIONS OF THE DRAWINGS

FIG. 1 is a side view of an electric power tool that is an embodiment of an electrical apparatus of the present invention;

FIG. 2 is a perspective view of a battery pack of the present invention;

FIG. 3 is a perspective view of a mounting unit of an electrical device of FIG. 1;

FIG. 4 is a bottom view showing a first embodiment of a cover used for the battery pack of the present invention;

FIG. 5 is a bottom view showing the first embodiment of the cover used for the battery pack of the present invention;

FIG. 6 is a bottom view showing a second embodiment of a cover used for the battery pack of the present invention;

FIG. 7A is an enlarged view of a main part of the cover of FIG. 6;

FIG. 7B is an enlarged view of the main part of the cover of FIG. 6;

FIG. 8A is an enlarged view of a main part of the cover of FIG. 6;

FIG. 8B is an enlarged view of the main part of the cover of FIG. 6;

FIG. 9A is an enlarged view of a main part of the cover of FIG. 6;

FIG. 9B is an enlarged view of the main part of the cover of FIG. 6;

FIG. 10 is a bottom view showing a third embodiment of a cover used for the battery pack of the present invention;

FIG. 11 is a bottom view showing a fourth embodiment of the cover used for the battery pack of the present invention;

FIG. 12 is a bottom view showing a fifth embodiment of a cover used for the battery pack of the present invention;

FIG. 13 is a bottom view showing the fifth embodiment of a cover used for the battery pack of the present invention;

FIG. 14 is a bottom view showing a sixth embodiment of the cover used for the battery pack of the present invention;

FIG. 15 is a bottom view showing the sixth embodiment of a cover used for the battery pack of the present invention;

FIG. 16 is an enlarged view of a main part of the cover of FIG. 11;

FIG. 17 is a side view of a seventh embodiment of the cover used for the battery pack of the present invention; and

FIG. 18 is a side view of the seventh embodiment of the cover used for the battery pack of the present invention.

### DESCRIPTIONS OF THE PREFERRED EMBODIMENTS

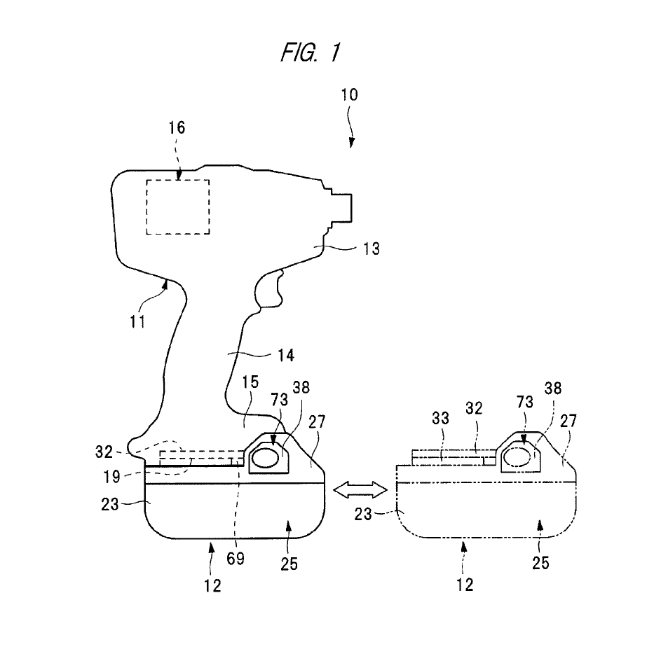

Embodiments of a battery pack and an electrical apparatus of the present invention will be described in detail, referring to the drawings. To describe the embodiments, an electric power tool 10 is described as an example of the electrical apparatus. As shown in FIGS. 1 to 3, the electric power tool 10 includes a tool body 11 and a battery pack 12 attached/detached to/from the tool body 11. The battery pack 12 can be attached to and detached from the tool body 11. The tool body 11 has a casing 13, a grip 14, and a mounting unit 15. An electric motor 16 is housed in the casing 13.

The casing 13 allows a tip tool to be attached/detached to/from the casing 13. When being supplied with power from the electric motor 16, the tip tool rotates or reciprocates around its axis. Applications of the electric power tool 10, therefore, include a drill, a screwdriver, an impact screwdriver, a hammer, a hammer drill, and a hammer screwdriver.

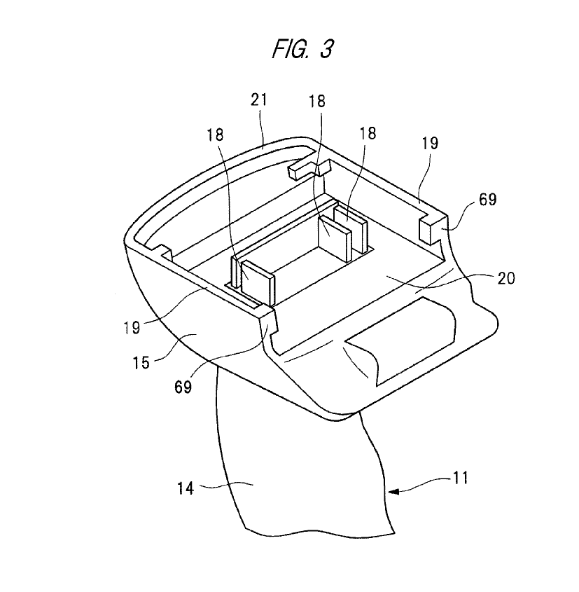

The casing 13 is connected to one end of the grip 14, while the mounting unit 15 is provided to the other end of the grip 14. The grip 14 has a hollow interior, in which a control board, etc., that controls the electric motor 16 is disposed. As shown in FIG. 3, the mounting unit 15 has multiple, e.g., three device-side terminals 18, which are made of a conductive metal material. The device-side terminals 18 are of a tabular shape and are so erected as to make a right angle with a flat surface 20 of the mounting unit 15. The device-side terminals 18 are parallel with each other, and are electrically connected to the control board via a cable (not illustrated).

The mounting unit 15 has two guide rails 19 formed across a given gap between them. The guide rails 19 are equivalent to a first guide unit of the present invention. In a bottom view of the mounting unit 15, the two guide rails 19 are parallel with each other and the flat surface 20 lies between these guide rails 19. The two guide rails 19 project against the flat surface 20 in the same direction in which the device-side terminals 18 project against the flat surface 20 of the mounting unit 15. The device-side terminals 18 are located between the two guide rails 19. A wall 21 is formed as a wall connecting both one ends in the longitudinal direction of the guide rails 19 of the mounting unit 15. Both of the other ends in the longitudinal direction of the guide rails 19 that are opposite to the wall 21 are provided with projections 69, respectively. The projections 69 project from the guide rails 19 in the direction of a plane parallel with the flat surface 20.

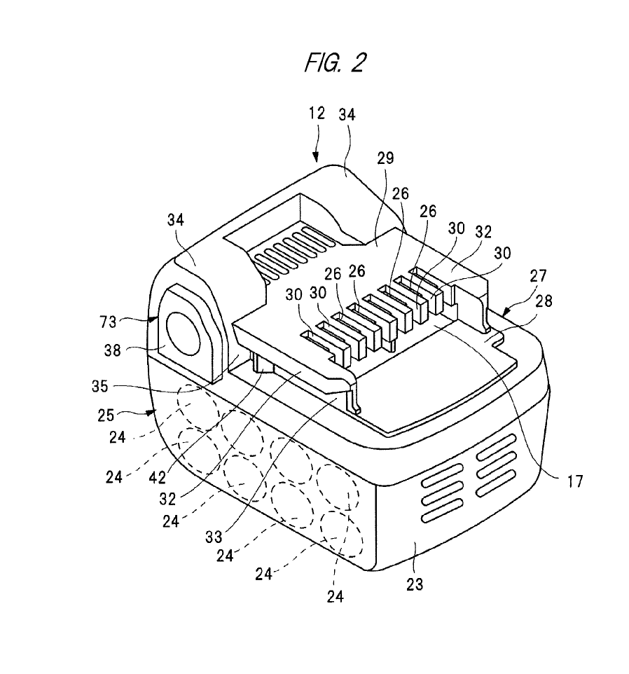

The battery pack 12 can be attached and detached to and from the mounting unit 15. A configuration of the battery pack 12 will be described referring to FIG. 2. The battery pack 12 has multiple battery cells 24 and a housing case 25 housing the multiple battery cells 24 therein. The battery cells 24 are secondary batteries capable of being charged and discharged repeatedly. The battery cells 24 include lithium ion battery cells, nickel-metal hydride battery cells, lithium ion polymer battery cells, and nickel-cadmium battery cells. The electrodes of the multiple battery cells 24 are connected to each other via connection boards (not illustrated), and the electrodes of battery cells located at an end of the direction of connection of the battery cells are connected to multiple battery-side terminals 26 via a circuit board (not illustrated).

The housing case 25 has a case body 23 and a cover 27 covering an opening of the case body 23. The case body 23 and the cover 27 are made of a non-conductive material and are separated from each other. The non-conductive material contains a resin. Embodiments of a structure in which the battery pack 12 is mounted to the mounting unit 15 will then be described in order.

### First Embodiment

The cover 27 has a flat plate portion 28 and a mount portion 29 different in height from the plate portion 28. The mount portion 29 has multiple terminal insertion holes 30 formed into slit-like shapes. The terminal insertion holes 30 communicatively connect the inside of the housing case 25 to the outside of the same. Each of the battery-side terminals 26 is inserted in each of the terminal insertion holes 30. An opening 17 is formed between the terminal insertion holes 30 and the plate portion 28. The opening 17 communicates with the terminal insertion holes 30.

The mount portion 29 is provided with two guide rails 32. The guide rails 32 are elements that come in contact with the guide rails 19 to regulate the direction of sliding of the housing case 25. The guide rails 32 are equivalent to a second guide unit of the present invention. The two guide rails 32 are located on both sides of the terminal insertion holes 30, respectively. In a plan view of the battery pack 12, the two guide rails 32 are arranged parallel with each other, and the guide rails 32 and the terminal insertion holes 30 are parallel with each other in their longitudinal direction. The two guide rails 32 overhang laterally from the mount portion 29, so that two guide grooves 33 are formed between two guide rails 32 and the surface of the cover 27, respectively. In a plan view of the battery pack 12, the two guide grooves 33 are parallel with each other. The guide rails 32 and the guide grooves 33 are equivalent to a guide mechanism of the present invention.

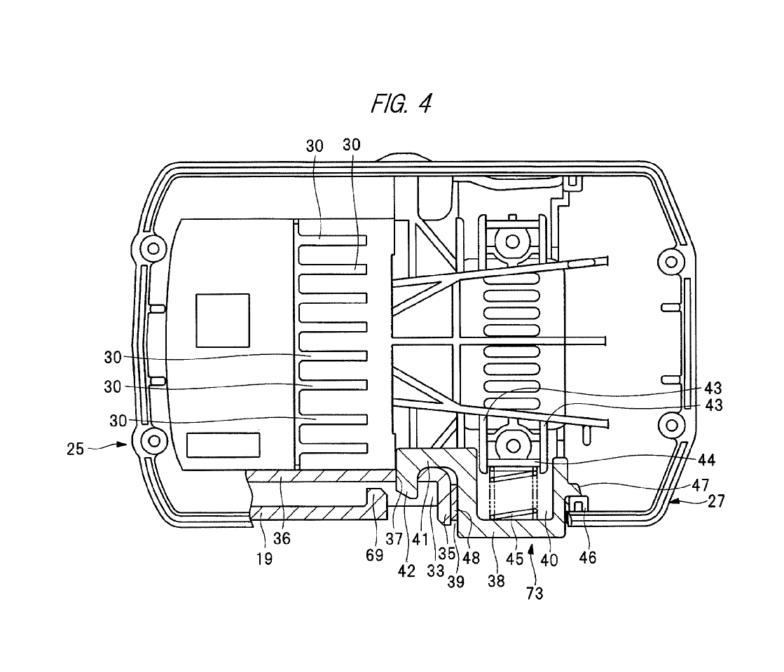

On the end of cover 27 that is opposite to the plate portion 28, two projections 34 are formed to be higher than the mount portion 29. Walls 35 are formed as walls forming the projections 34. In a bottom view of the cover 27, as shown in FIG. 4, the walls 35 are formed to be perpendicular to the guide grooves 33. Two walls 36 forming part of the cover 27 are provided to ends of the two guide grooves 33, respectively, such that the walls 36 are parallel with each other. In a bottom view of the cover 27, the walls 36 and the walls 35 are perpendicular to each other and are continuous with each other. Holes 37 penetrating the walls 36 are formed thereon.

Latch mechanisms 73 are attached to the sides of both projections 34 of the cover 27, respectively. Each latch mechanism 73 has an operation part 38. Each projection 34 has a hole 39, in which the operation part 38 is disposed. Each latch mechanism 73 extends from the inside to the outside of the cover 27. A concave portion 40 is provided in the part of operation part 38 that is recessed inside the cover 27. The latch mechanism 73 has an arm 41 extending from the operation part 38 in a direction along the guide groove 33, and a claw 42 is provided to the front end of the arm 41. In other words, a part of the operation part 38 is bent into a hook shape. The latch mechanism 73 of the present invention includes the operation part 38 and the claw 42.

In a bottom view of the cover 27, the claw 42 projects in the direction perpendicular to the guide groove 33. The arm 41 is disposed inside the cover 27, and the claw 42, which can be moved to the hole 37, is inserted in the hole 37. In a bottom view of the cover 27, the width of the claw 42 in the longitudinal direction of the guide groove 33 is smaller than the width of the hole 37. The front end of the claw 42 is disposed in the guide groove 33.

Two ribs 43 are formed on the inner surface of the cover 27. The two ribs 43 are formed in the direction perpendicular to the guide groove 33, and are disposed in the concave portion 40. On the inner surface of the cover 27, a rib 44 is formed between the two ribs 43. In a bottom view of the cover 27, a gap is formed between the two ribs 43 and the inner surface of the concave portion 40. This allows the latch mechanism 73 to reciprocate in the direction perpendicular to the guide groove 33 in a bottom view of the cover 27. In a bottom view of the cover 27, the latch mechanism 73 can move along the longitudinal direction of the guide groove 33 relative to the cover 27, according to the size of a gap between the hole 37 and the claw 42 and the size of a gap between the two ribs 43 and the inner surface of the concave portion 40.

A compression coil spring 45 is disposed in the concave portion 40. The compression coil spring 45 is molded integrally out of a metal material, and the latch mechanism 73 is pushed with the force of the compression coil spring 45 toward the outside of the cover 27. A stopper 46 is formed on the inner surface of the cover 27. The operation part 38 is provided with a projection 47. When the latch mechanism 73 is pushed by the compression coil spring 45, the projection 47 comes into contact with the stopper 46 as the arm 41 comes into contact with the wall 36, stopping the latch mechanism 73.

In a bottom view of the cover 27, an elastic member 48 serving as an energizing member is interposed between the wall portion 35 and the operation part 38. The elastic member 48 is molded integrally with, for example, rubber, and is fixed to the wall portion 35 or the operation part 38. The elastic member 48 is bonded or joined to the wall portion 35 or the operation part 38 by an adhesive, double-faced adhesive tape, double-layer molding, etc.

When the latch mechanism 73 is being attached to the cover 27, the elastic member 48 is sandwiched between the operation part 38 and the wall portion 35 and is compressed in the longitudinal direction of the guide groove 33. As a result, in a bottom view of the cover 27, the latch mechanism 73 is pushed with the elastic restoring force of the elastic member 48 in the longitudinal direction of the guide groove 33. Specifically, the latch mechanism 73 is pushed by the elastic member 48 in a direction in which the latch mechanism 73 moves away from the terminal insertion holes 30. In other words, in a bottom view of the cover 27, the latch mechanism 73 is pushed in a direction in which a gap between the claw 42 and the wall portion 35 is narrowed in the longitudinal direction of the guide groove 33.

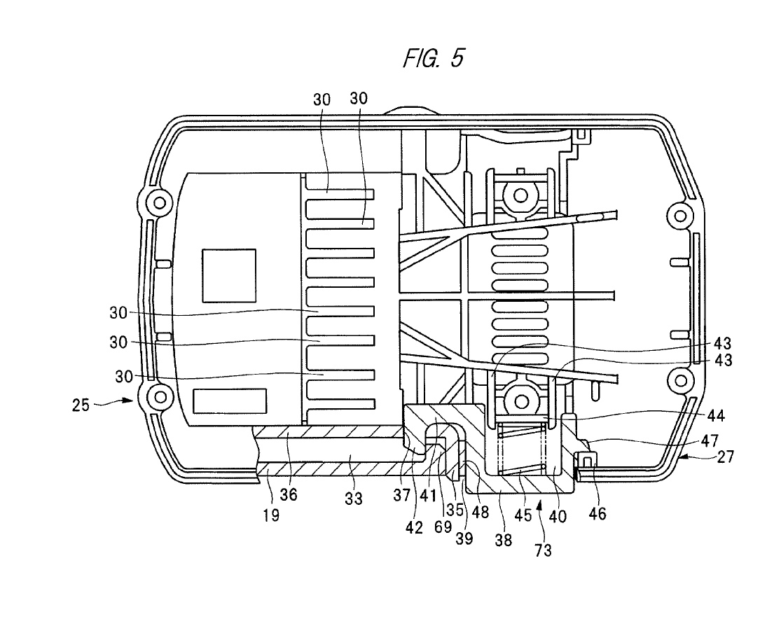

FIGS. 4 and 5 depict the structures of the wall 36, wall portion 35, operation part 38, ribs 43 and 44, compression coil spring 45, elastic member 48, hole 39, projection 47, stopper 46, etc., corresponding to one of the two guide grooves 33 provided to the cover 27. However, the same constituent elements and structures as these constituent elements and structures are provided in correspondence to the other one of the guide grooves 33 in a horizontally symmetrical arrangement.

Work of mounting the battery pack 12 to the mounting unit 15 of the tool body 11 will then be described. When the battery pack 12 is not attached to the tool body 11, as indicated by a two-dot chain line in FIG. 1, the latch mechanism 73 is pushed with the force of the compression coil spring 45, bringing the projection 47 into contact with the stopper 46 and the arm 41 into contact with the wall 36.

When the tool body 11 is moved closer to the battery pack 12, the projection 69 comes into the guide groove 33, which means that the guide rail 19 comes into contact with the guide rail 32. As a result, the tool body 11 and the battery pack 12 are regulated in the direction of their relative move to each other, that is, in the direction of their sliding over each other. Subsequently, as shown in FIG. 4, when the projection 69 approaches the claw 42 and causes it to climb onto the projection 69, the latch mechanism 73 moves toward the interior of the cover 27 against the force of the compression coil spring 45. As a result, the projection 47 moves away from the stopper 46 as the arm 41 moves away from the wall 36.

When the battery pack 12 is moved further closer to the mounting unit 15 and the front end of the guide rail 19 comes into contact with the wall portion 35 of the cover 27 as the claw 42 climbs over the projection 69, as shown in FIG. 5, the latch mechanism 73 subjected to the force of compression coil spring 45 moves toward the outside of the cover 27. This causes the claw 42 and the projection 69 to engage with each other. At the same time, the projection 47 comes into contact with the stopper 46 as the arm 41 comes into contact with the wall 36, stopping the latch mechanism 73. When the battery pack 12 is mounted to the mounting unit 15, the device-side terminals 18 come into the terminal insertion holes 30 and are connected to the battery-side terminals 26.

When the battery pack 12 is slid and mounted to the mounting unit 15 in this manner, the claw 42 and the projection 69 engage with each other, as shown in FIG. 5, which keeps the battery pack 12 being mounted to the mounting unit 15, as shown in FIG. 1. In this state, the latch mechanism 73 is pushed with the force of the elastic member 48 along the longitudinal direction of the guide groove 33 in a direction in which the latch mechanism 73 moves away from the mounting unit 15. As a result, when the claw 42 is in its state of ingress in the guide groove 33, that is, in its state of engagement with the projection 69, the projection 69 is kept sandwiched (clamped) between the claw 42 and the wall portion 35 with the force of the elastic member 48.

In other words, a gap between the front end of the guide rail 19 and the wall portion 35 of the cover 27 is narrowed. More specifically, in the direction of mounting of the battery pack 12 to the mounting unit 15, i.e., mounting direction, the wall portion 35 is pressed against the front end of the guide rail 19 in a direction in which the battery pack 12 and the mounting unit 15 approach each other. This prevents the battery pack 12 and the mounting unit 15 from moving relative to each other in the longitudinal direction of the guide rail 19, that is, prevents the rattling of the battery pack 12 and the mounting unit 15. The ingress of an external foreign object, such as dust, dirt, sand, etc. into a gap between the mounting unit 15 and the battery pack 12, therefore, can be inhibited.

Note that, when the battery pack 12 is to be detached from the mounting unit 15, a worker presses the operation part 38 to move the latch mechanism 73 against the force of the compression coil spring 45. This disengages the claw 42 from the projection 69 and allows the battery pack 12 and the mounting unit 15 to slid along the guide rails 19 and 32 in a direction in which the battery pack 12 and the mounting unit 15 move away from each other. Hence the battery pack 12 is detached from the mounting unit 15.

### Second Embodiment

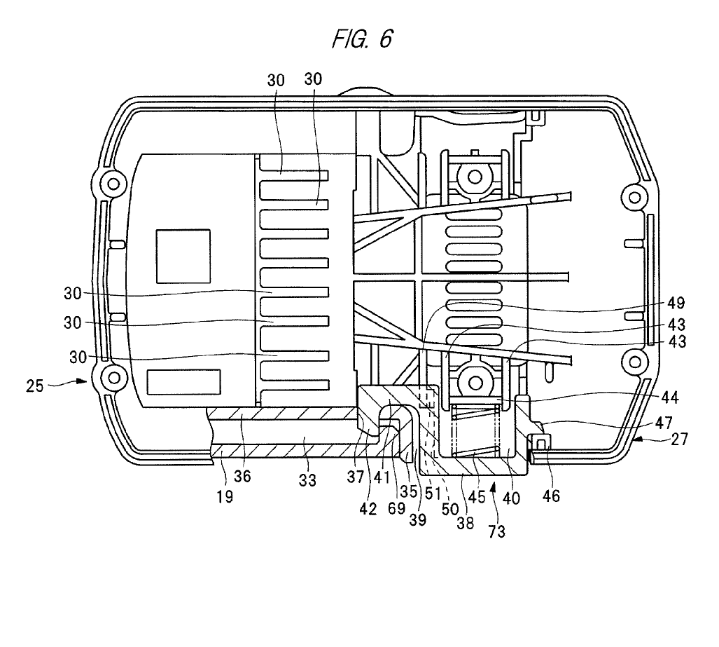

A second embodiment of the cover 27 used for the battery pack 12 of FIGS. 1 and 2 will be described, referring to FIG. 6. The same structural parts of the cover 27 of FIG. 6 as structural parts of the cover 27 of FIGS. 4 and 5 are denoted by the same reference numerals used in FIGS. 4 and 5. According to the cover 27 of FIG. 6, on the inner surface of the cover 27, a rib 49 is formed between the rib 43 and the terminal insertion holes 30. The rib 49 is parallel with the ribs 43.

A rib 50 is provided to the operation part 38 such that the rib 50 is located between the ribs 43 and the rib 49 in the longitudinal direction of the guide groove 33. An elastic member 51 serving as an energizing member is interposed between the rib 49 and the rib 50. The elastic member 51 is fixed to either the rib 49 or the rib 50, and is molded integrally with rubber, etc. When the latch mechanism 73 is being attached to the cover 27, the elastic member 51 is compressed and elastically deformed by the ribs 49 and 50. As a result, in a bottom view of the cover 27, the elastic member 51 pushes the latch mechanism 73 along the longitudinal direction of the guide rails 19 and 32 in a direction in which the latch mechanism 73 moves away from the mounting unit 15. Specifically, the latch mechanism 73 is pushed with the force of the elastic member 51 in a direction in which the gap between the claw 42 and the wall portion 35 is narrowed.

Work of mounting the battery pack 12 having the cover 27 of FIG. 6 to the mounting unit 15 of the tool body 11 will then be described. When the battery pack 12 is not attached to the tool body 11, as indicated by a two-dot chain line in FIG. 1, the latch mechanism 73 is pushed with the force of the compression coil spring 45, which brings the projection 47 into contact with the stopper 46 and the arm 41 into contact with the wall 36.

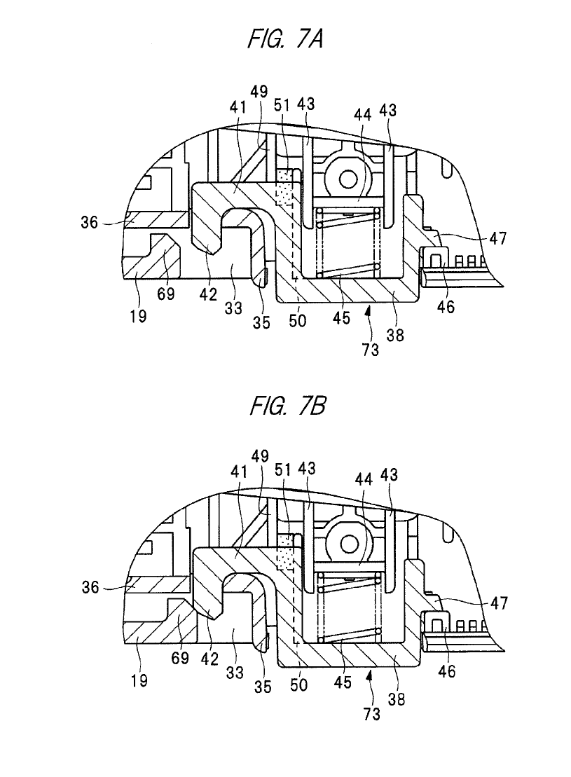

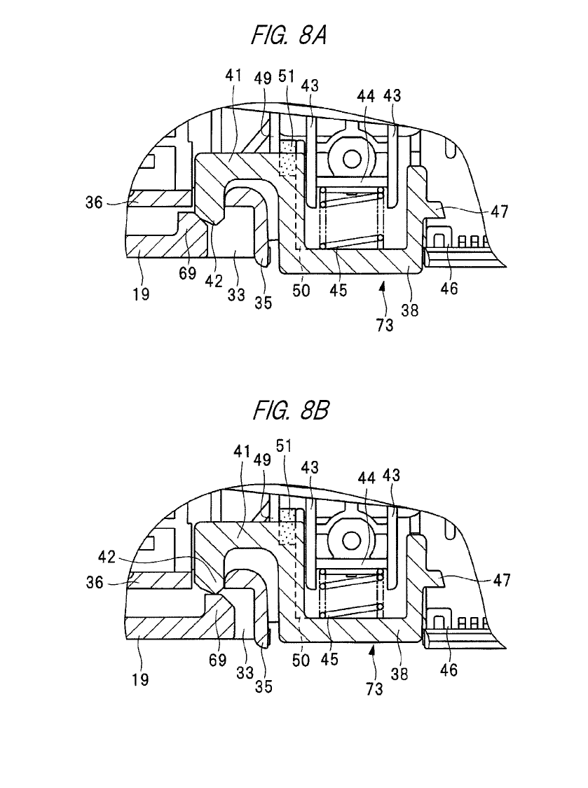

When the tool body 11 is moved closer to the battery pack 12, the projection 69 comes into the guide groove 33, as shown in FIG. 7A, which means that the guide rails 19 and 32 limit the directions of the tool body 11 and the battery pack 12 to move relatively to each other. Then, as shown in FIG. 7B, when the projection 69 comes into contact with the claw 42, the claw 42 is pushed by the projection 69, which forces the latch mechanism 73 to move against the force of the compression coil spring 45. This causes the claw 42 to start climbing up on the projection 69, as shown in FIG. 8A, thus allowing the battery pack 12 to keep moving. Finally, as shown in FIG. 8B, the claw 42 has completely climbed up on the front end of the projection 69.

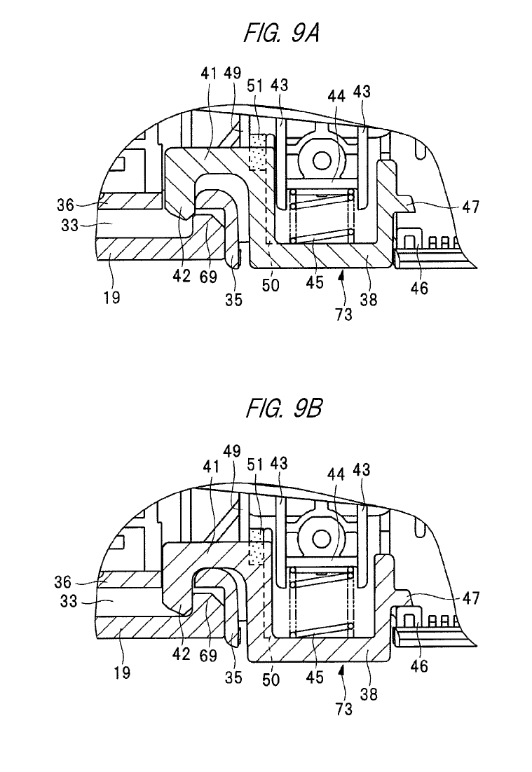

Subsequently, when the battery pack 12 is further moved closer to the mounting unit 15, the claw 42 climbs over the front end of the projection 69, as shown in FIG. 9A. As a result, the latch mechanism 73 subjected to the force of compression coil spring 45 moves toward the wall 36. Then, as shown in FIG. 9B, the projection 47 comes into contact with the stopper 46 as the arm 41 comes into contact with the wall 36, stopping the latch mechanism 73, at which the claw 42 and the projection 69 engage with each other.

When the battery pack 12 is mounted to the mounting unit 15 in this manner, the claw 42 and the projection 69 engage with each other, as shown in FIG. 6, which keeps the battery pack 12 mounted to the mounting unit 15, as shown in FIG. 1. In this state, the latch mechanism 73 is pushed with the force of the elastic member 51 along the longitudinal direction of the guide groove 33. As a result, when the claw 42 is in its state of ingress in the guide groove 33, that is, in its state of engagement with the projection 69, the projection 69 is kept sandwiched (clamped) between the claw 42 and the wall portion 35 with the force of the elastic member 51. This prevents the battery pack 12 from coming off from the mounting unit 15.

The latch mechanism 73 is pushed with the force of the elastic member 51 along the longitudinal direction of the guide groove 33 in the direction in which the latch mechanism 73 moves away from the mounting unit 15. As a result, the projection 69 is kept sandwiched (clamped) between the claw 42 and the wall portion 35 with the force of the elastic member 51. Hence, as described above, the rattling of the battery pack 12 and the mounting unit 15 is suppressed and the ingress of an external foreign object into the gap between the mounting unit 15 and the battery pack 12 is inhibited. The work to carryout to detach the battery pack 12 from the mounting unit 15 is the same as the above-described work of detaching the battery pack 12.

### Third Embodiment

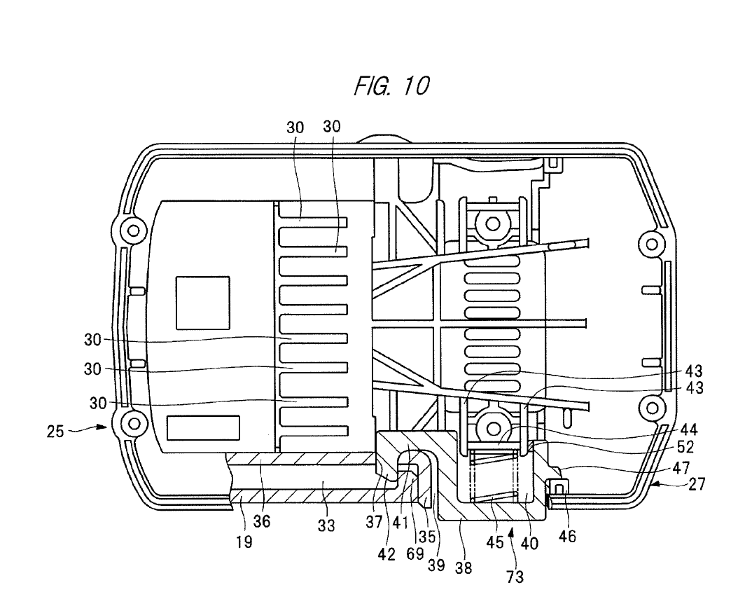

A third embodiment of the cover 27 used for the battery pack 12 of FIGS. 1 and 2 will be described, referring to FIG. 10. The same structural parts of the cover 27 of FIG. 10 as structural parts of the cover 27 of FIGS. 4 and 5 are denoted by the same reference numerals used in FIGS. 4 and 5. According to the cover 27 of FIG. 10, an elastic member 52 serving as an energizing member is interposed between one of two ribs 43 that is located on the far side to the guide groove 33 and the inner surface of the concave portion 40. The elastic member 52 is fixed to either the rib 43 or the inner surface of the concave portion 40, and is molded integrally with rubber, etc.

When the latch mechanism 73 is in its state of attachment to the cover 27, the elastic member 52 is compressed and elastically deformed by the rib 43 and the inner surface of the concave portion 40. As a result, in a bottom view of the cover 27, the elastic member 52 pushes the latch mechanism 73 along the longitudinal direction of the guide rails 19 and 32 in the direction in which the latch mechanism 73 moves away from the mounting unit 15. Specifically, the latch mechanism 73 is pushed with the force of the elastic member 52 in the direction in which the gap between the claw 42 and the wall portion 35 is narrowed.

The resulting effect of mounting the battery pack 12 having the cover 27 of FIG. 10 to the mounting unit 15 of the tool body 11 is the same as that of mounting the battery pack 12 having the cover 27 of FIGS. 4 and 5 to the mounting unit 15 of the tool body 11.

When the battery pack 12 is mounted to the mounting unit 15 in this manner, the claw 42 and the projection 69 engage with each other, as shown in FIG. 10, which prevents the battery pack 12 from coming off from the mounting unit 15. In this state, the latch mechanism 73 is pushed with the force of the elastic member 52 along the longitudinal direction of the guide groove 33. As a result, when the claw 42 is in its state of ingress in the guide groove 33, the projection 69 is kept sandwiched (clamped) between the claw 42 and the wall portion 35 with the force of the elastic member 52. This offers the same effect as that of the first embodiment of the cover 27, by which the rattling of the battery pack 12 and the mounting unit 15 is suppressed and the ingress of an external foreign object into the gap between the mounting unit 15 and the battery pack 12 is inhibited.

The work to carry out to detach the battery pack 12 from the mounting unit 15 is the same as the work of detaching the battery pack 12 described above in the first embodiment of the cover 27.

### Fourth Embodiment

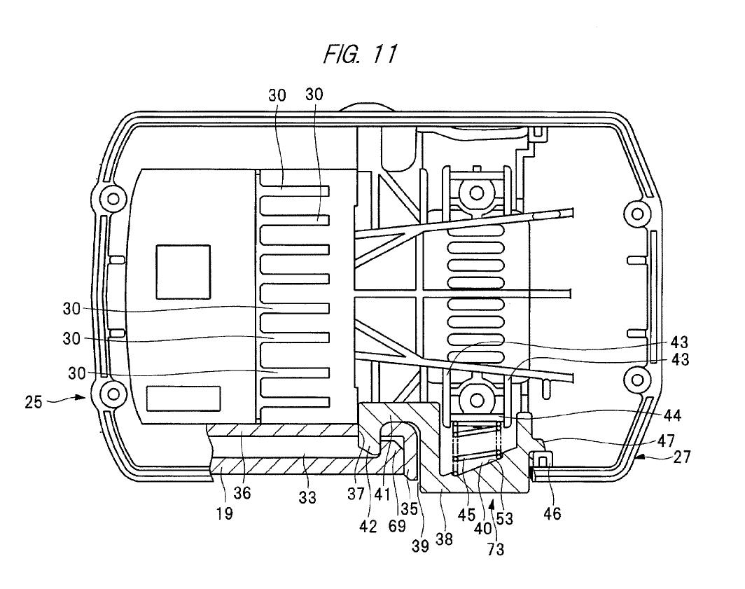

A fourth embodiment of the cover 27 used for the battery pack 12 of FIGS. 1 and 2 will be described, referring to FIG. 11. The same structural parts of the cover 27 of FIG. 11 as structural parts of the cover 27 of FIGS. 4 and 5 are denoted by the same reference numerals used in FIGS. 4 and 5. In a bottom view of the cover 27 of FIG. 11, the bottom face 53 of the concave portion 40 crosses a straight line extending along the guide groove 33, which means that the bottom face 53 is sloped. Specifically, the bottom face 53 is sloped in a direction in which a gap between the bottom face 53 and the rib 44 becomes wider as the bottom face 53 comes closer to the guide groove 33. An end of the compression coil spring 45 is in contact with the bottom face 53. The cover 27 of FIG. 11 is not provided with a constituent element corresponding to the above-mentioned elastic members 48, 51, and 52.

When the latch mechanism 73 is in its state of attachment to the cover 27, the compression coil spring 45 pushes the operation part 38 in a direction along the ribs 43, and is in contact with the bottom face 53 of the concave portion 40. As a result, the latch mechanism 73 is subjected not only to a force acting in the longitudinal direction of the ribs 43 but also to a component of force acting in a direction crossing the longitudinal direction of the ribs 43. Hence the latch mechanism 73 is pushed with the component of force in the longitudinal direction of the guide groove 33, which narrows the gap between the claw 42 and the wall portion 35.

The resulting effect of mounting the battery pack 12 having the cover 27 of FIG. 11 to the mounting unit 15 of the tool body 11 is the same as that of mounting the battery pack 12 having the cover 27 of FIGS. 4 and 5 to the mounting unit 15 of the tool body 11.

When the battery pack 12 is mounted to the mounting unit 15 in this manner, the claw 42 and the projection 69 engage with each other, as shown in FIG. 11, which prevents the battery pack 12 from coming off from the mounting unit 15. In this state, the latch mechanism 73 is pushed with the force of the compression coil spring 45 in the longitudinal direction of the guide groove 33. As a result, the projection 69 is kept sandwiched (clamped) between the claw 42 and the wall portion 35 with the force of the elastic member 52. This offers the same effect as the effect of the first embodiment of the cover 27, by which the rattling of the battery pack 12 and the mounting unit 15 is suppressed and the ingress of an external foreign object into the gap between the mounting unit 15 and the battery pack 12 is inhibited.

According to the fourth embodiment of the cover 27, the compression coil spring 45 has a function of pushing the latch mechanism 73 in the direction perpendicular to the guide rails 19 and 32 and also has a function of pushing the latch mechanism 73 in the longitudinal direction of the guide rails 19 and 32. It is therefore unnecessary to provide a dedicated elastic member that pushes the latch mechanism 73 in the longitudinal direction of the guide rails 19 and 32. As a result, an increase in the number of components of the cover 27 is prevented. In the fourth embodiment, the compression coil spring 45 is equivalent to an energizing member.

The work to carry out to detach the battery pack 12 from the mounting unit 15 is the same as the work of detaching the battery pack 12 described above in the first embodiment of the cover 27.

### Fifth Embodiment

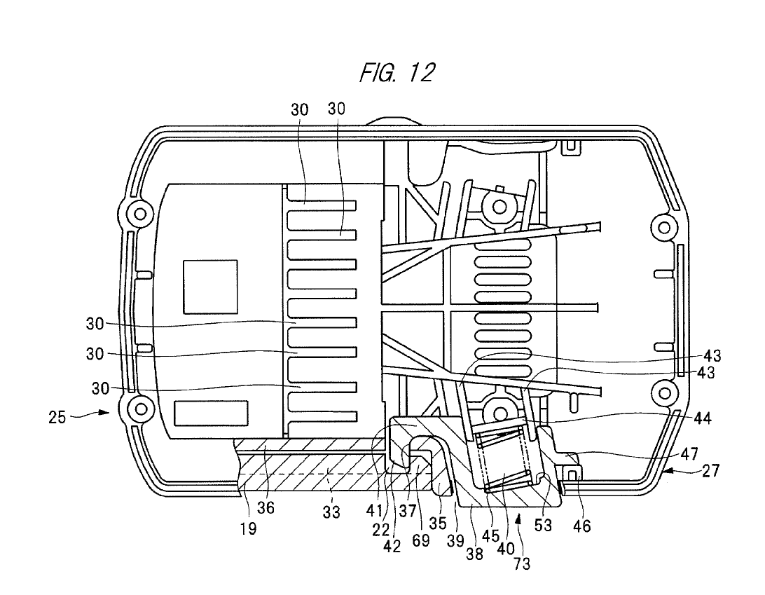

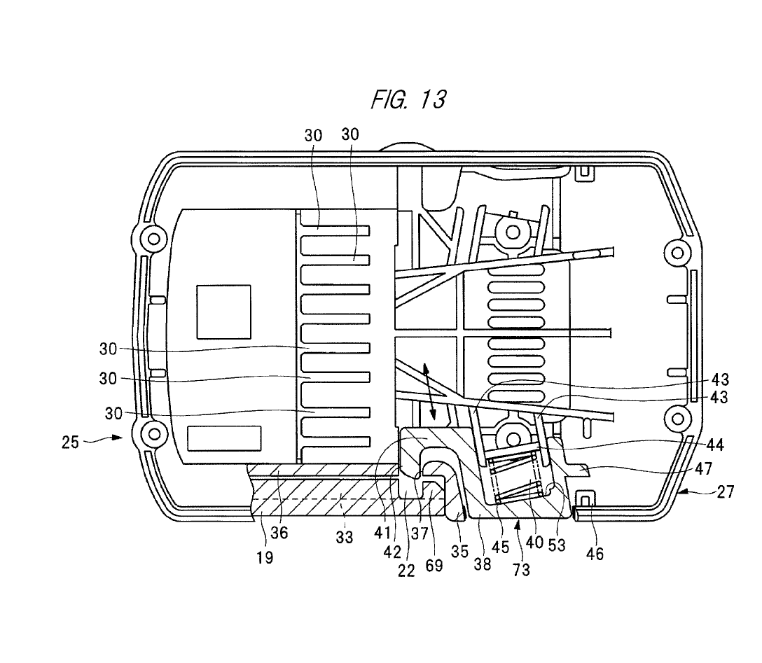

A fifth embodiment of the cover 27 used for the battery pack 12 of FIGS. 1 and 2 will be described, referring to FIGS. 12 and 13. The same structural parts of the cover 27 of FIGS. 12 and 13 as structural parts of the cover 27 of FIG. 11 are denoted by the same reference numerals used in FIG. 11. According to the cover 27 of FIGS. 12 and 13, in a bottom view of the cover 27, the two ribs 43 are extended in a direction not perpendicular to the guide groove 33. Specifically, the two ribs 43 are tilted in a direction in which the ribs 43 move closer to the terminal insertion holes 30 as the ribs 43 moves away from the hole 39.

The rib 44 is provided to be perpendicular to the two ribs 43 and parallel with the bottom face 53 of the concave portion 40. The inner surface of the concave portion 40 extends in parallel with the two ribs 43. The surface of a part of wall portion 35 that is close to the operation part 38 is parallel with the ribs 43. Apart of surface of the operation part 38 that is in contact with the wall portion 35 extends in parallel with the ribs 43. The latch mechanism 73 attached to the cover 27 of FIGS. 9 and 10 is capable of moving in parallel with the two ribs 43. The cover 27 of FIGS. 12 and 13 has no constituent element corresponding to the above-described elastic members 48, 51, and 52.

When the operation part 38 is in its state of attachment to the cover 27, the compression coil spring 45 pushes the latch mechanism 73 toward the outside of the cover 27 and is in contact with the bottom face of the concave portion 40. As a result, the latch mechanism 73 is subjected to a force acting in the longitudinal direction of the ribs 43, and a component of this force pushes the latch mechanism 73 in the longitudinal direction of the guide groove 33. As a result, the gap between the claw 42 and the wall portion 35 is narrowed.

The resulting effect of mounting the battery pack 12 having the cover 27 of FIGS. 12 and 13 to the mounting unit 15 of the tool body 11 is the same as the resulting effect of mounting the battery pack 12 having the cover 27 of FIGS. 4 and 5 to the mounting unit 15 of the tool body 11.

When the battery pack 12 is mounted to the mounting unit 15 in this manner, the claw 42 is fitted in the concave portion 22, engaging the claw 42 and the projection 69 with each other as shown in FIG. 12. This prevents the battery pack 12 from coming off from the mounting unit 15. In this state, the latch mechanism 73 is pushed with the force of the compression coil spring 45 in the longitudinal direction of the guide groove 33. As a result, the projection 69 is kept sandwiched (clamped) between the claw 42 and the wall portion 35 with the force of the elastic member 52. This offers the same effect as the effect of the first embodiment of the cover 27, by which the rattling of the battery pack 12 and the mounting unit 15 is suppressed and the ingress of an external foreign object into the gap between the mounting unit 15 and the battery pack 12 is inhibited.

According to the fifth embodiment of the cover 27, the compression coil spring 45 has a function of pushing the latch mechanism 73 toward the outside of the cover 27 and also has a function of pushing the latch mechanism 73 in the longitudinal direction of the guide rails 19 and 32. It is therefore unnecessary to provide a dedicated elastic member that pushes the latch mechanism 73 in the longitudinal direction of the guide rails 19 and 32. As a result, an increase in the number of components of the cover 27 is prevented. In the fifth embodiment, the compression coil spring 45 is equivalent to an energizing member.

Work of detaching the battery pack 12 from the mounting unit 15 is carried out in such a way that pressing the operation part 38 causes the latch mechanism 73 to move along the two ribs 43, thereby disengages the claw 42 from the projection 69, as shown in FIG. 13.

### Sixth Embodiment

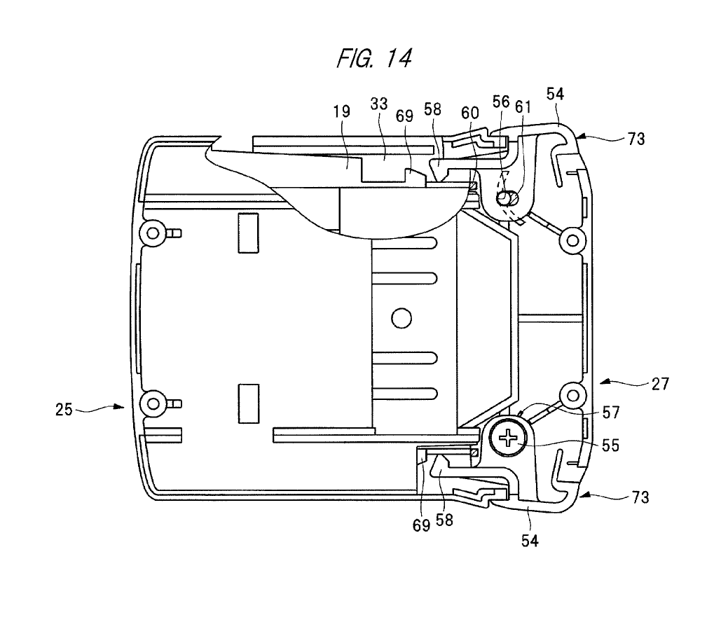

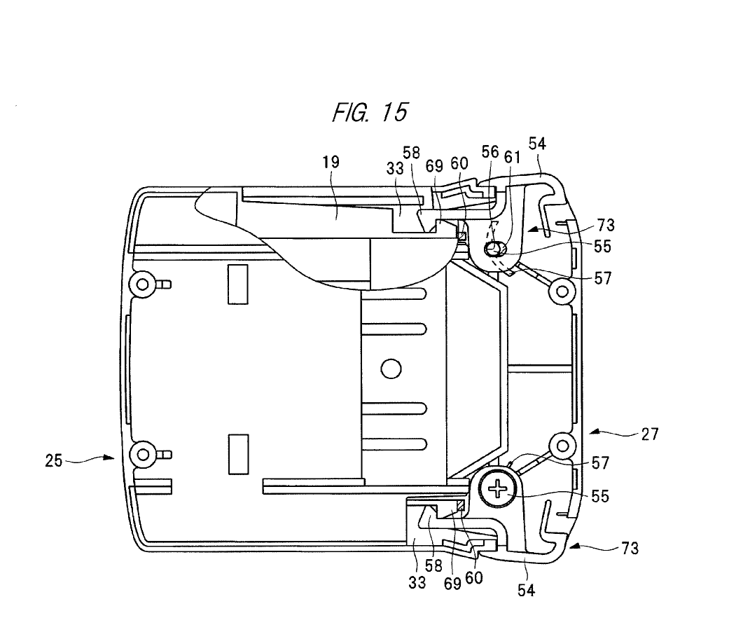

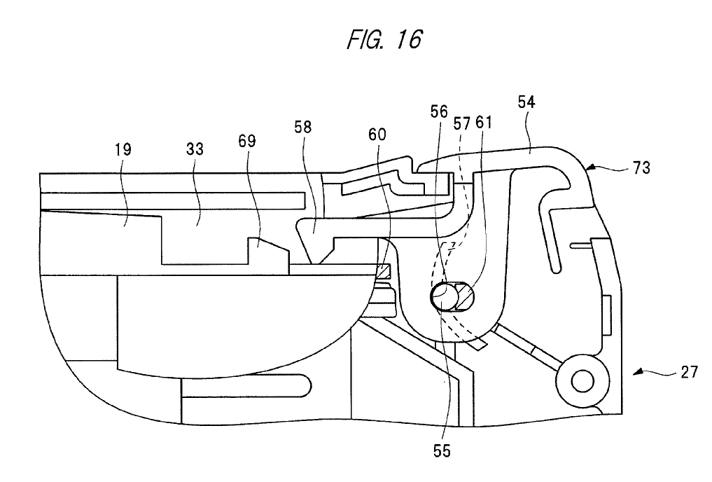

A sixth embodiment of the cover 27 used for the battery pack 12 of FIGS. 1 and 2 will be described, referring to FIGS. 14 to 16. The same structural parts of the cover 27 of FIGS. 14 to 16 as structural parts of the cover 27 of FIG. 4 are denoted by the same reference numerals used in FIG. 4. The cover 27 of FIGS. 14 and 15 is provided with two operation parts 54. In a bottom view of the cover 27, each of the two operation parts 54 can rotate around a support shaft 55 in a given range of angle. Each operation part 54 has a fitting hole 56 in which the support shaft 55 is fitted. The fitting hole 56 is an elongated hole having a major axis extending in a direction along the guide groove 33. The operation part 54 can move in the direction of major axis of the fitting hole 56. The support shaft 55 is fitted with a torsion coil spring 57 that applies its force to the operation part 54.

The two operation parts 54 have two claws 58, respectively, which project in a direction in which the claws 58 face each other. The latch mechanism 73 of the present invention includes the operation parts 54 and the claws 58. A part of the operation part 54 rotated with the force of the torsion coil spring 57 comes into contact with the cover 27, stopping the operation part 54 from rotating. On the inner surface of the cover 27, a bearing unit 60 is formed, which is located between the claw 58 and the support shaft 55. The bearing unit 60 projects in the longitudinal direction of the support shaft 55 from the inner surface of the cover 27. An elastic member 61 serving as an energizing member is disposed in the fitting hole 56. The elastic member 61 is molded integrally with rubber. Being in contact with the inner surface of the fitting hole 56 and with the surface of the support shaft 55, the elastic member 61 is compressed and elastically deformed by the fitting hole 56 and support shaft 55. The elastic member 61 creates a force that pushes the latch mechanism 73 along the longitudinal direction of the guide rails 19 and 32 in the direction in which the latch mechanism 73 moves away from the mounting unit 15. Specifically, the latch mechanism 73 is pushed in a direction in which the claw 58 approaches the bearing unit 60.

Work of mounting the battery pack 12 having the cover 27 of FIG. 15 to the mounting unit 15 will be described. When the battery pack 12 is moved closer to the mounting unit 15, the projection 69 comes into contact with the claw 58, thereby applies a force from the projection 69 to the operation part 54. As a result, the latch mechanism 73 rotates around the support shaft 55 against the force of the torsion coil spring 57, which causes the claw 58 to climb up on the projection 69. Afterward, as shown in FIG. 15, when the claw 58 has climbed over the projection 69, the operation part 54 is rotated by the force of the torsion coil spring 57, and a part of the operation part 54 comes into contact with the cover 27, which stops the rotation of the operation part 54.

Because the elastic member 61 pushes the latch mechanism 73 along the longitudinal direction of the guide groove 33 in the direction in which the latch mechanism 73 moves away from the mounting unit 15, the projection 69 is kept sandwiched (clamped) between the claw 58 and the bearing unit 60. As a result, the bearing unit 60 is pressed against the front end of the guide rail 19 in the direction of mounting the battery pack 12 to the mounting unit 15. In other words, a gap between the projection 69 and the bearing unit 60 is narrowed in the longitudinal direction of the guide groove 33. Hence, when the battery pack 12 is being mounted to the mounting unit 15, the battery pack 12 and the mounting unit 15 are prevented from moving relatively to each other in the longitudinal direction of the guide groove 33. As described above, the battery pack 12 having the cover 27 of the sixth embodiment offers the same effect as the battery pack 12 of the first embodiment does.

To detach the battery pack 12 having the cover 27 of FIG. 15 from the mounting unit 15, the operation part 54 is rotated against the force of the torsion coil spring 57 to disengage the claw 58 from the projection 69, and the battery pack 12 and the mounting unit 15 are moved relatively to each other in a direction in which the battery pack 12 moves away from the mounting unit 15.

### Seventh Embodiment

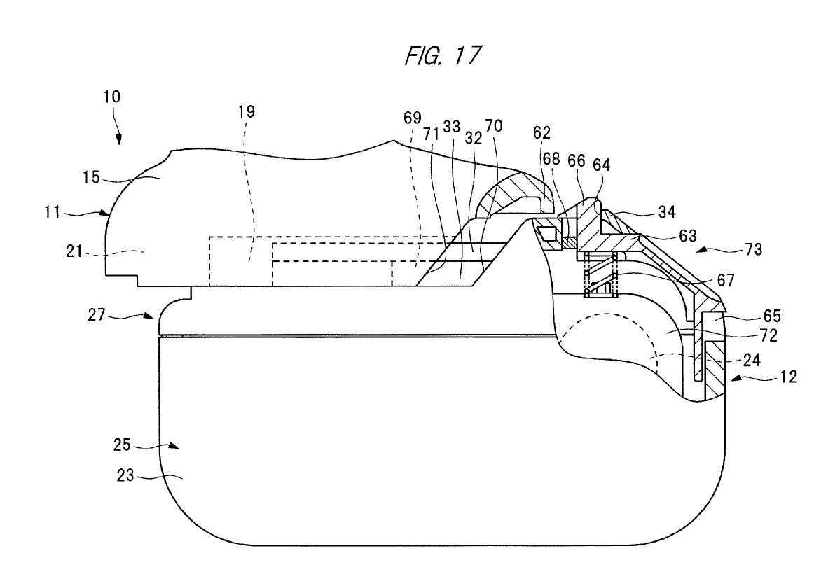

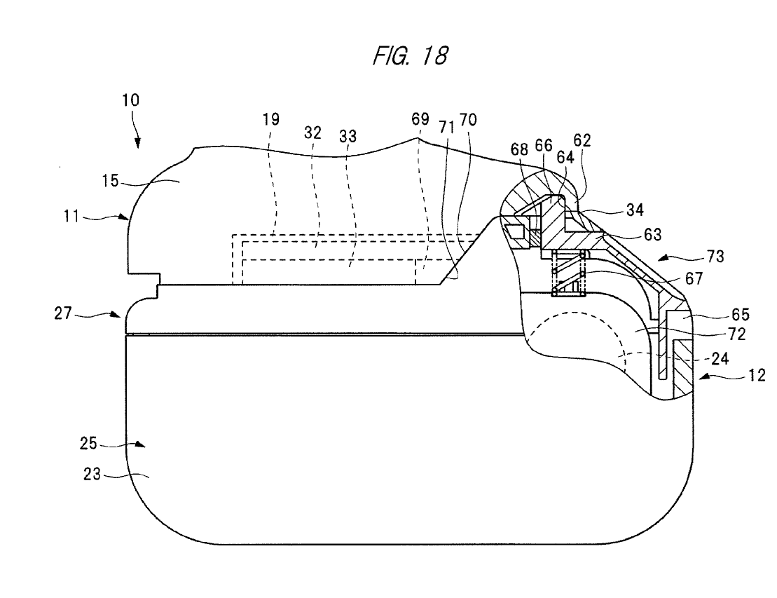

A seventh embodiment of the cover 27 used for the battery pack 12 of FIGS. 1 and 2 will be described, referring to FIGS. 17 and 18. The same structural parts of the mounting unit 15 and the cover 27 of FIGS. 17 and 18 as structural parts of the mounting unit 15 of FIG. 3 and the cover 27 of FIG. 4 are denoted by the same reference numerals used in FIGS. 3 and 4. The mounting unit 15 of FIGS. 17 and 18 has a projection 62 provided to the end of mounting unit 15 that is opposite to the wall 21 in the longitudinal direction of the guide rail 19. The projection 62 projects in a direction crossing the longitudinal direction of the guide rail 19.

An operation part 63 is attached to the cover 27. The operation part 63 is disposed on the projection 34 of the cover 27. An insertion hole 64 is formed as an opening on the top face of the projection 34, and a fitting hole 65 is formed by cutting out part of the cover 27. The operation part 63 is fitted in the fitting hole 65, and is capable of moving up and down in views of FIGS. 17 and 18. The operation part 63 is provided with a claw 66, which projects upward and is inserted in the insertion hole 64. The latch mechanism 73 of the present invention includes the operation part 63 and the claw 66.

A spring 67 is disposed inside the housing case 25, and the operation part 63 is pushed upward with the force of the spring 67. A holder 72 holding battery cells 24 is disposed inside the housing case 25, and the spring 67 is interposed between the holder 72 and the operation part 63. The spring 67 is a compression spring made of metal. The operation part 63 pushed by the spring 67 comes into contact with the inner surface of the fitting hole 65, which stops the operation part 63 from moving.

An elastic member 68 serving as an energizing member is attached to the cover 27. The elastic member 68 is molded integrally with rubber, and is compressed and elastically deformed between the operation part 63 and the cover 27. The elastic member 68 creates a force that pushes the latch mechanism 73 along the longitudinal direction of the guide rails 19 and 32 in the direction in which the latch mechanism 73 moves away from the mounting unit 15.

Work of mounting the battery pack 12 having the cover of FIGS. 17 and 18 to the mounting unit 15 will be described. The battery pack 12 is moved closer to the mounting unit 15 to cause the projection 69 to move along the guide groove 33. As a result, the projection 62 comes into contact with the claw 66, causing the operation part 63 to move closer to the case body 23 against the force of the spring 67. The claw 66 thus climbs up on the projection 62. Subsequently, when the claw 66 has climbed over the projection 62, the operation part 63 is moved by the force of the spring 67 in a direction in which the operation part 63 moves away from the case body 23. The operation part 63 then comes into contact with the inner surface of the fitting hole 65 and is stopped from moving. At the same time, a sloped surface 70 continuous with the projection 34 comes into contact with a sloped surface 71 the mounting unit 15 has. Hence the work of mounting the battery pack 12 to the mounting unit 15 is completed.

When the battery pack 12 is mounted to the mounting unit 15 in this manner, the claw 66 is engaged with the projection 62 and the force of the elastic member 68 is transmitted to the mounting unit 15 via the latch mechanism 73. As a result, in the longitudinal direction of the guide rail 32, the sloped surface 70 is pressed against the sloped surface 71 in the direction of mounting the battery pack 12 to the mounting unit 15, which reduces the size of a gap between the sloped surface 70 and the sloped surface 71. Hence the relative move of the battery pack 12 and the mounting unit 15 to each other in the longitudinal direction of the guide rail 32, that is, the rattling of the battery pack 12 and the mounting unit 15 is prevented. As described above, the battery pack 12 having the cover 27 of the seventh embodiment also offers the same effect as offered by the battery pack 12 of the first embodiment.

In FIG. 18, the battery pack 12 is detached from the mounting unit 15 in the following manner. The operation part 63 is pressed to cause it to move closer to the case body 23 against the force of the spring 67 so that the claw 66 is disengaged from the projection 62. Then, the battery pack 12 and the mounting unit 15 are moved relatively to each other in the direction in which the battery pack 12 moves away from the mounting unit 15.

The present invention is not limited to the above first to seventh embodiments and may be modified into various forms provided that modifications do not deviate from the substance of the invention. For example, applications of the electrical apparatus of the present invention include not only the above electric power tool but also a grinder, sander, clawing machine, screw-driving machine, tucker, dust collector, blower, pump, high-pressure washer, chain saw, mowing machine, clippers, and cultivator. Applications of the electrical device of the present invention include equipment that rotates an electric motor with power from a battery pack and that converts the rotation into either the reciprocation or rotation of an operating member.

Applications of the electrical apparatus of the present invention also include a torch, etc., that is, equipment that converts electric energy supplied from a battery pack into optical energy. Applications of the first and second guides of the present invention include guide rails coming in contact with each other and a combination of a guide rail and a guide groove.

States of right angle, parallel, and perpendicular described in this specification include states of incomplete right angle, incomplete parallel, and incomplete perpendicular resulting from insufficient processing precision of constituent elements, assembling errors, etc. In other words, strictly speaking, states of right angle, parallel, and perpendicular include states of substantially right angle, substantially parallel, and substantially perpendicular.

What is claimed is:

1. A battery pack comprising:
a housing case slidably attached/detached to/from an electrical device; and
an energizing member for exerting a force acting in a direction of causing a mounting unit provided to the electrical device and the housing case to move closer to each other.

2. A battery pack comprising:
a housing case slidably attached/detached to/from an electrical device; and
an energizing member for, when the housing case is being mounted to a mounting unit provided to the electrical device, exerting a force acting in a direction of causing the mounting unit and the housing case to move closer to each other.

3. The battery pack according to claim 1, wherein
a latch mechanism having a claw that is engaged with the mounting unit and an operation part that operates the claw is housed in the housing case, and wherein
the energizing member is disposed between the housing case and the latch mechanism.

4. A battery pack comprising:
a housing case for housing a battery cell and attached/detached to/from an electrical device;
a latch mechanism including a claw provided to the housing case, the claw being engaged with a mounting unit provided to the electrical device, and an operation part disposed on the housing case, the operation part operating the claw; and
an energizing member for, when the housing case is being mounted to the mounting unit, exerting a force acting in a direction of causing the mounting unit and the housing case to move closer to each other.

5. A battery pack comprising:
a housing case for housing a battery cell and attached/detached to/from an electrical device;
a latch mechanism having a claw provided to the housing case, the claw being engaged with a mounting unit provided to the electrical device, and an operation part disposed on the housing case, the operation part operating the claw; and
an energizing member for, when the housing case is mounted to the mounting unit, applying energy to the latch mechanism in a direction of causing the latch mechanism to move away from the mounting unit.

6. The battery pack according to claim 4, wherein
a second guide guided by a first guide provided to the mounting unit is provided to the housing case,
the claw is engaged with a projection provided to the mounting unit, and
the energizing member applies energy to the latch mechanism in a direction along the second guide.

7. An electrical apparatus comprising:
an electrical device; and
a battery pack including:
a housing case slidably attached/detached to/from the electrical device; and
an energizing member for exerting a force acting in a direction of causing a mounting unit provided to the electrical device and the housing case to move closer to each other.

8. A battery pack comprising:
a housing case housing a battery cell and attached/detached to/from an electrical device; and
an energizing member disposed in the housing case, the energizing member pushing the housing case to the electrical device in a direction in which the housing case is attached to the electrical device.

9. The battery pack according to claim 8, wherein
the energizing member is an elastic member.

10. The battery pack according to claim 8, wherein
a claw is provided to the housing case, the claw being engaged with a projection provided to the electrical device to keep the battery pack attached to the electrical device, and
the energizing member pushes the housing case to the projection.

11. The battery pack according to claim 8, wherein
the housing case has a sloped surface, the sloped surface being extended in a direction crossing a direction of attaching the housing case to the electrical device, and wherein
the energizing member pushes the sloped surface to the electrical device.

12. The battery pack according to claim 10, wherein
an operation part is disposed on the housing case, the operation part disengaging the claw from the projection, and wherein
the claw is provided to the operation part.

13. The battery pack according to claim 8, comprising a guide mechanism disposed on the housing case, the guide mechanism determining a direction of move of the housing case relative to the electrical device.

14. An electrical apparatus comprising:
a battery pack including a housing case housing a battery cell and attached/detached to/from an electrical device and an energizing member disposed in the housing case, the energizing member pushing the housing case to the electrical device in a direction in which the housing case is attached to the electrical device; and
the electrical device to/from which the battery pack is attached/detached.

15. The electrical apparatus according to claim 14, comprising:
a battery-side terminal disposed on the battery pack; and
a device-side terminal disposed on the electrical device, the device-side terminal being connected to the battery-side terminal when the battery pack is attached to the electrical device.
